(19) United States
(12) Patent Application Publication
(10) Pub. No.: US 2026/0293273 A1
(43) Pub. Date: Sep. 24, 2026

(54) LATERAL ELECTRICAL PATH FROM CONTACT TO CONTACT

(71) Applicant: Taiwan Semiconductor Manufacturing Company, Ltd., Hsinchu (TW)

(72) Inventors: KeJing Yu, Kaohsiung City (TW); Ru-Shang Hsiao, Jhubei City (TW); Nai-Chyi Chang, Taichung City (TW); Sheng Yu Lin, Taoyuan City (TW)

(73) Assignee: Taiwan Semiconductor Manufacturing Company, Ltd., Hsinchu (TW)

(21) Appl. No.: 19/085,383

(22) Filed: Mar. 20, 2025

(51) Int. Cl. H10D 84/01; H10D 64/23; H10D 64/62; H10D 84/83

(52) U.S. Cl. CPC H10D 84/0147; H10D 64/258; H10D 64/62; H10D 84/0149; H10D 84/8316

(57) ABSTRACT

Semiconductor structures and methods of fabrication are provided. A method includes forming a trench over a semiconductor substrate, wherein the trench has a trench sidewall; forming a semiconductor liner on the trench sidewall; converting at least a portion of the semiconductor liner to a metal-semiconductor intermetallic; forming a first conductive contact in the trench, wherein the first conductive contact contacts the metal-semiconductor intermetallic; and forming a second conductive contact adjacent to the metal-semiconductor intermetallic.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography and etching processes to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise within each of the processes that are used, and these additional problems should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method for fabricating a semiconductor structure, in accordance with certain embodiments.

FIGS. 2-13 illustrate cross-sectional views of intermediate processing stages of the method of FIG. 1 for fabricating a semiconductor structure, according to certain embodiments.

FIG. 14 illustrates an alternate embodiment as compared to FIG. 13, in accordance with certain embodiments.

FIGS. 15-20 illustrate cross-sectional views of intermediate processing stages of the method of FIG. 1 for fabricating a semiconductor structure, according to certain embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. The present disclosure relates more particularly to interconnect structures for integrated circuit devices. Methods described herein may be easily integrated into the current process flow.

More specifically, embodiments herein provide for electrically connecting a source/drain contact to a gate contact through a self-aligned silicide layer, or other semiconductor intermetallic layer. As a result, no additional contact material needs to be formed and interconnected above the source/drain contact and the gate contact, and the electrical path from source/drain feature to gate structure is shortened.

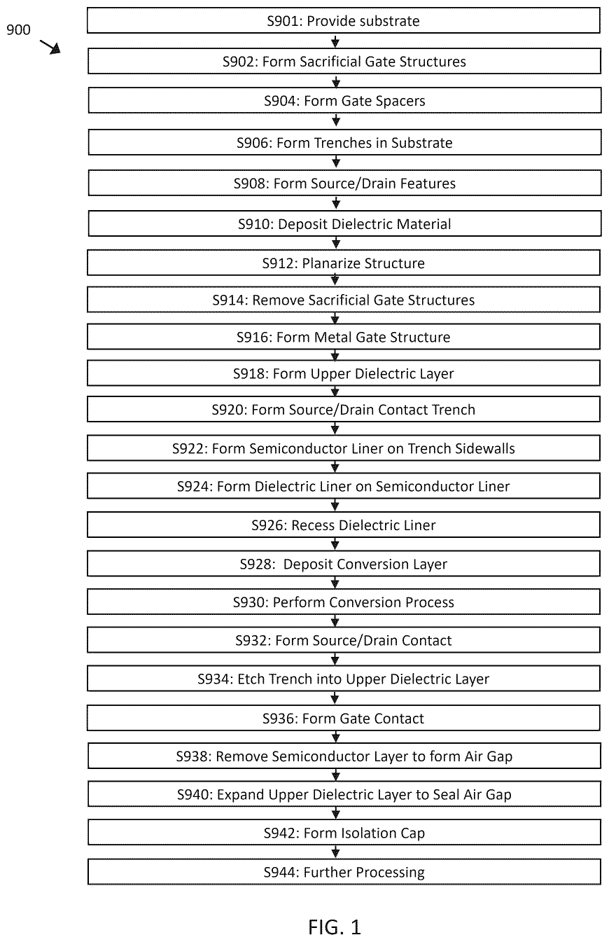

Referring to FIG. 1, a method 900 for forming a semiconductor structure or device 100 is illustrated in a flow chart, according to various aspects of the present disclosure.

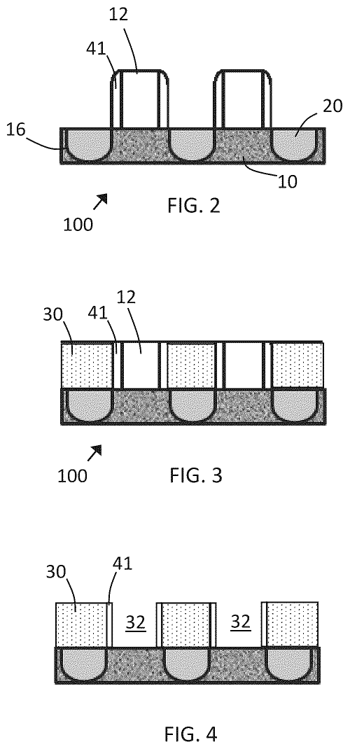

FIG. 1 is described in conjunction with FIGS. 2-13 or 14, which illustrate a semiconductor structure or device 100 at various stages of fabrication in accordance with some embodiments of the present disclosure of the method 900. The method 900 is merely an example, and is not intended to limit the present disclosure beyond what is explicitly recited in the claims. Additional steps may be provided before, during, and after method 900, and some of the steps described can be moved, replaced, or eliminated for additional embodiments of method 900. Additional features may be added in the semiconductor device depicted in the Figures and some of the features described below can be replaced, modified, or eliminated in other embodiments of the semiconductor device.

The semiconductor devices 100 may be transistors and/or may be planar FET devices, FinFET devices, gate-all-around (GAA) devices, CFET devices, advanced devices, industry semi-completed products or other devices or products.

As with other method embodiments and exemplary devices discussed herein, it is understood that parts of the semiconductor structure 100 may be fabricated by typical semiconductor technology process flow, such as SRAM process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the process steps of method 900, including any descriptions given with reference to the Figures, as with the remainder of the method and exemplary figures provided in this disclosure, are merely exemplary and are not intended to be limiting beyond what is specifically recited in the claims that follow.

At operation S901, the method 900 (FIG. 1) provides a substrate 10, as shown in FIG. 2. In some embodiments, the substrate 10 may be a semiconductor substrate such as a silicon (Si) substrate. The substrate 10 may include various layers, including conductive or insulating layers formed on a semiconductor substrate. The substrate 10 may include various doping configurations depending on design requirements as is known in the art. For example, different doping profiles (e.g., p-well, n-well) may be formed on the substrate 10 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 10 includes a single crystalline semiconductor layer on at least its surface portion. The substrate 10 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 10 may include a compound semiconductor and/or an alloy semiconductor. In the illustrated embodiment, the substrate 10 is made of crystalline Si.

Still referring to FIG. 2, at operation S902, the method 900 (FIG. 1) may form dummy gate structures 12 over the substrate 10. The gate structures 12 may include a dummy gate dielectric, a dummy gate electrode, and a hard mask. The gate structures 12 may be formed by deposition, lithography patterning, and/or etching processes as known in the art.

The dummy gate dielectric is formed over the substrate 10 and may include a dielectric material, such as silicon oxide, silicon oxynitride, silicon nitride, a high dielectric constant (high-k) dielectric material, other suitable dielectric material, or combinations thereof. Exemplary high-k dielectric materials include HfO2, HfSiO, HfSiON, HfTaO, HfSiO, HfZrO, other suitable materials, or combinations thereof.

The dummy gate electrode is formed over the dummy gate dielectric. In some embodiments, the gate electrode is formed by a polycrystalline silicon (polysilicon) layer.

The hard mask formed over the gate electrode may include silicon oxide, silicon nitride, silicon oxynitride, silicon carbide, other suitable dielectric material, or combinations thereof. The hard mask may have a multi-layer structure.

Still referring to FIG. 2, at operation S904, the method 900 (FIG. 1) may form gate spacers 41 overlying opposite sidewalls of the gate structure 12. For example, a first spacer material may be deposited over the gate structure 12 and the substrate 10. The first spacer material may be formed by plasma-enhanced chemical vapor deposition (PECVD) and/or other suitable processes. In at least one embodiment, the first spacer material is a dielectric layer including silicon oxide. Thereafter, a second spacer material is deposited over the first spacer material. The second spacer material may be deposited using physical vapor deposition (PVD) (sputtering), chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), and/or other suitable processes. In at least one embodiment, the second spacer material is a dielectric layer including silicon nitride. Other exemplary compositions for the second spacer material include silicon oxide, silicon carbide, silicon oxynitride, silicon oxycarbonitride (SiOCN) combinations thereof, and/or other suitable materials.

After the formation of the first and second spacer materials over the gate structure 12, a patterning process, e.g., blanket dry etching process, is performed on the first and second spacer materials to form gate spacers 41. The etching process may include an anisotropic etch to partially remove the first and second spacer materials from the substrate 10 in regions where epitaxy features or raised source/drain features will be formed.

Still referring to FIG. 2, the method 900 (FIG. 1) continues with operation S906 in which trenches 16 are formed in the substrate 10 at either side of the gate structure 12, particularly in the source and drain regions of the PFET device or the NFET device.

A capping layer (not shown) and a photoresist layer (not shown) may be formed over the semiconductor device 100 and then patterned to protect the other device region. The photoresist layer may further include an antireflective coating layer (not shown), such as a bottom antireflective coating (BARC) layer and/or a top antireflective coating (TARC) layer. An etching process then removes portions of the substrate 10 to form the trenches 16 in the substrate 10. The etching process includes a dry etching process, wet etching process, or combination thereof. In some embodiments, the etching process utilizes a combination of dry and wet etching processes. The dry and wet etching processes have etching parameters that can be tuned, such as etchants used, etching temperature, etching solution concentration, etching pressure, source power, RF bias voltage, RF bias power, etchant flow rate, and other suitable parameters.

Still referring to FIG. 2, at operation S908, the method 900 (FIG. 1) continues with forming source/drain features 20 in the trenches 16.

As used herein, “source/drain region(s)” or “source/drain feature(s)” may refer to a source or a drain, individually or collectively dependent upon the context.

For example, operation S908 may include growing epitaxial material in the trenches 16 to form source/drain features 20. It is noted that the source/drain features 20 may be formed by successive formed layers. In exemplary embodiments, the source/drain features 20 are strained source/drain features 20. Also, the source/drain features 20 may be formed with layers selected for use in an NFET or PFET. In exemplary embodiments, the source/drain features 20 may include N-type epitaxial material source/drain features and P-type epitaxial material source/drain features. The epitaxial material may include one or more layers of Si, SiP, SiC and SiCP for an N-channel FET or Si, SiGe, Ge for a P-channel FET. For the P-channel FET, boron (B) may also be contained in the source/drain. The source/drain epitaxial layers may be formed by an epitaxial growth method using CVD, ALD, or molecular beam epitaxy (MBE).

Referring now to FIG. 3, at operation S910, the method 900 (FIG. 1) continues with depositing a dielectric material 30, such as an interlayer dielectric (ILD) over the substrate 10. Specifically, the dielectric material 30 may be formed over source/drain features 20 and along the sides of the sidewall spacers 41. The dielectric material 30 may be silicon oxide or other suitable dielectric material. In certain embodiments, the dielectric material may further include a dielectric liner, such as silicon nitride or another suitable material.

As shown in FIG. 3, the structure 100 may be planarized at operation S912 (FIG. 1), such as by a chemical-mechanical planarization (CMP) process. Planarization may remove the mask and uncover the sacrificial gate electrode of gate structure 12.

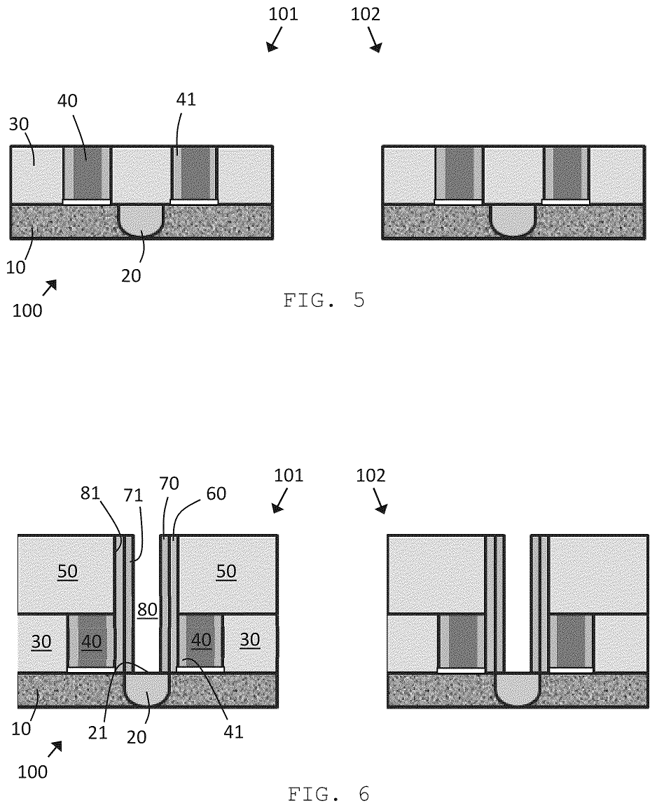

Referring now to FIG. 4, at operation S914, the method 900 (FIG. 1) continues with removing the sacrificial gate structure 12. As shown, the sacrificial gate structures are removed to form gate cavities 32 between sidewall spacers 41.

FIG. 5 illustrates two regions 101 and 102 of the substrate 10 and device 100 to describe different processing by method 900 in the different regions 101 and 102. It is noted that FIG. 5 and the following Figures illustrate only one source/drain feature 20 for simplicity.

Referring now to FIG. 5, at operation S916, the method 900 (FIG. 1) continues with forming metal gates 40 in the gate cavities 32. As shown, operation S916 is performed in device regions 101 and 102.

Specifically, method 900 may include forming an interfacial layer along the cavity bottom and then lining the gate cavities 32 with a dielectric layer. For example, the interfacial layer may be silicon oxide (SiOx), and the dielectric layer may be a high-K gate dielectric layer deposited on the sidewalls of gate cavities 32. High-K gate dielectrics, as used and described herein, include dielectric materials having a high dielectric constant, for example, greater than that of thermal silicon oxide (about 3.9). An exemplary high-K gate dielectric layer may include a high-K dielectric material such as hafnium oxide (HfO₂). Alternatively, the high-K gate dielectric layer may include other high-K dielectric materials, such as TiO₂, HfZrO, Ta₂O₃, HfSiO₄, ZrO₂, ZrSiO₂, LaO, AlO, ZrO, TiO, Ta₂O₅, Y2O₃, SrTiO₃ (STO), BaTiO₃ (BTO), BaZrO, HfZrO, HfLaO, HfSiO, LaSiO, AlSiO, HfTaO, HfTiO, (Ba, Sr)TiO₃ (BST), Al₂O₃, Si₃N₄, oxynitrides (SiON), combinations thereof, or other suitable material. The high-K gate dielectric layer may be formed by ALD, physical vapor deposition (PVD), CVD, oxidation, and/or other suitable methods.

Formation of the metal gates 40 further includes filling the gate cavities 32 with electrode fill material. The fill material may include multiple layers of a metal, metal alloy, or metal silicide. The fill material may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the fill material may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the fill material may be formed by ALD, PVD, CVD, e-beam evaporation, or other suitable process. Further, the fill material may be formed separately for N-type and P-type transistors which may use different metal layers. In addition, the fill material may provide an N-type or P-type work function, may serve as a transistor gate electrode, and in at least some embodiments, the fill material may include a polysilicon layer. In some examples, the fill material may include selectively-grown tungsten (W) and/or a fluorine-free tungsten (FFW) layer.

As shown in FIG. 5, forming the metal gates 40 in the gate cavities 32 may include performing a chemical mechanical planarization (CMP) process to remove overburden portions of the liner and fill material to define the metal gates 40 in the gate cavities 32. As shown, the dielectric material 30 may be defined as segments between the metal gates 40.

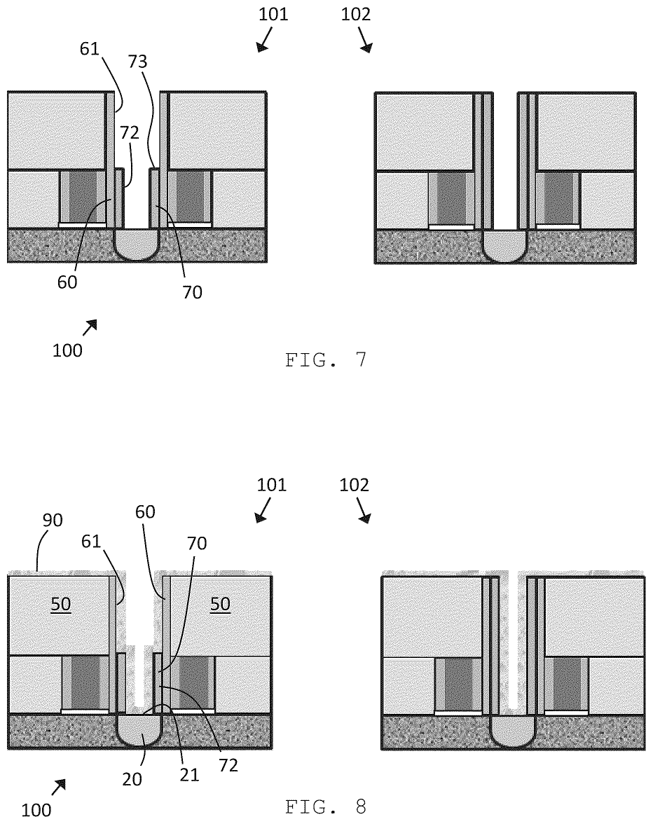

Referring now to FIG. 6, at operation S918, the method 900 (FIG. 1) continues with forming an upper dielectric layer 50 over the metal gate structure 40 and the dielectric segments 30. As shown, operation S918 is performed in device regions 101 and 102.

The upper dielectric layer 50 may be an interlayer dielectric (ILD). The dielectric material 30 may be silicon oxide or other suitable dielectric material. In certain embodiments, the dielectric material may further include a dielectric liner, such as silicon nitride or another suitable material.

Still referring to FIG. 6, the method 900 (FIG. 1) continues at operation S920 with forming a trench 80 over the semiconductor substrate 10. Specifically, operation S920 includes performing an etch process to remove the portion of the upper dielectric layer 50 lying over a selected source/drain feature 20, and to remove the lower dielectric segment 30 lying over the selected source/drain feature 20. As shown, operation S920 is performed in device regions 101 and 102.

The trench 80 may be formed in accordance with known photolithography and etching techniques. The etching process may be an anisotropic or isotropic etch process. In an embodiment the etching process is an anisotropic dry etch process. In an embodiment, the etch process is continued until an upper surface 21 of the source/drain feature 20 is exposed, i.e., uncovered. As shown, the trench 80 is formed with sidewalls 81. Sidewalls 81 may be formed by sidewall spacers 41 and upper dielectric layer 50. The upper surface 21 of the source/drain feature 20 forms the trench bottom surface.

With continued reference to FIG. 6, the method 900 (FIG. 1), at operation S922, forms a semiconductor liner 60 on sidewalls 81 of the trench 80. As shown, operation S922 is performed in device regions 101 and 102.

For example, a semiconductor liner material may be conformally deposited over the structure 100. Then, an anisotropic etch may be performed to remove the lateral or horizontal portions of the semiconductor liner material (overlying the upper surface of structure 100 and overlying the trench bottom surface 21). As a result, the semiconductor liner 60 is formed on the sidewalls 81 of the trench 80.

In certain embodiments, the semiconductor liner material is or includes silicon, though the semiconductor liner material may be or include other semiconductor materials. In certain embodiments, the semiconductor liner 60 is a silicon liner 60.

Still referring to FIG. 6, the method 900 (FIG. 1) continues at operation S924 with forming a dielectric liner 70 over the semiconductor liner 60 in the trench 80. As shown, operation S924 is performed in device regions 101 and 102.

For example, a dielectric liner material may be conformally deposited over the structure 100. Then, an anisotropic etch may be performed to remove the lateral or horizontal portions of the dielectric liner material (overlying the upper surface of structure 100 and overlying the trench bottom surface 21). As a result, the dielectric liner 70 is formed on the semiconductor liner 60 over the sidewalls 81 of the trench 80.

In certain embodiments, the dielectric liner material is or includes silicon nitride, though the dielectric liner material may be or include other dielectric materials. In certain embodiments, the dielectric liner 70 is a silicon nitride liner 70.

In certain embodiments, the dielectric liner 70 and the gate spacers 41 comprise different materials.

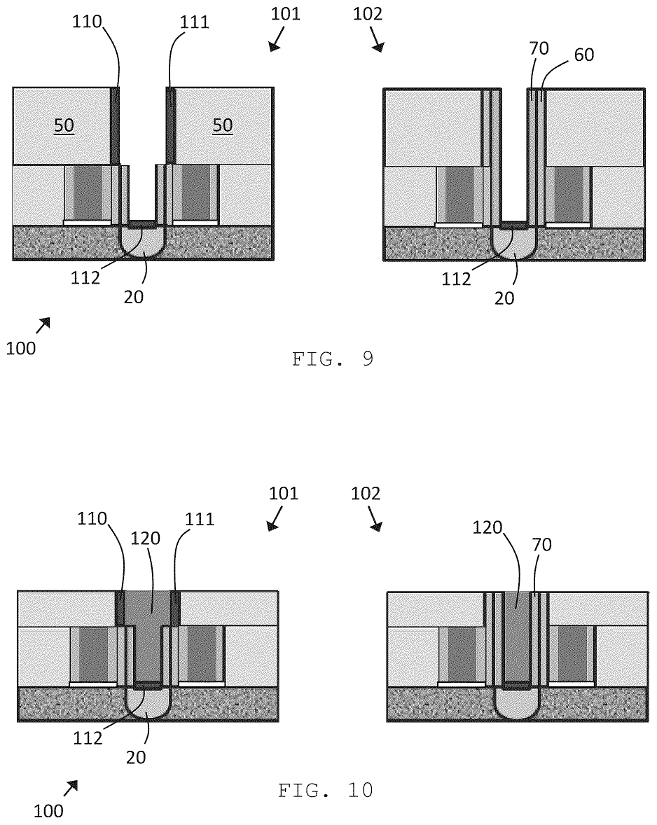

Referring now to FIG. 7, the method 900 (FIG. 1) continues at operation S926 with recessing the dielectric liner 70, i.e., removing upper portions 71 of the dielectric liner 70. As shown, operation S926 is performed only in device region 101. For example, device region 102 may be masked while operation S926 is performed.

As shown in FIG. 7, a lower portion 72 of the dielectric liner 70 may remain after operation S926. Lower portion 72 has a top surface 73. As a result of removing the upper portion 71 of the dielectric layer 70, an upper portion 61 of semiconductor layer 60 is uncovered. As shown in FIG. 7, in device region 102, the semiconductor layer 60 remains covered by the dielectric layer 70.

It is noted that while FIG. 7 illustrates that the dielectric liner 70 is recessed on both, opposite sides of trench. However, in certain embodiments, the photo mask may be shifted to provided for etching only one side, such as the left side in the Figures, while the dielectric liner 70 on the other side remains unetched.

Referring now to FIG. 8, at operation S928, the method 900 (FIG. 1) includes depositing a conversion layer 90 over the structure 100 in device regions 101 and 102. As shown, the conversion layer 90 is conformally deposited. In device region 101, the conversion layer 90 contacts the uncovered portion 61 of semiconductor layer 60 and the upper surface 21 of the source/drain feature 20, as well as the remaining portion 72 of dielectric layer 70 and the top surface of upper dielectric 50. In device region 102, the conversion layer 90 contacts the upper surface 21 of the source/drain feature 20, but the semiconductor layer 60 is shielded from the conversion layer 90 by the dielectric layer 70.

In certain embodiments, the conversion layer 90 is or includes a metal. For example, the conversion layer may be or may include titanium, nickel, cobalt, or another suitable metal.

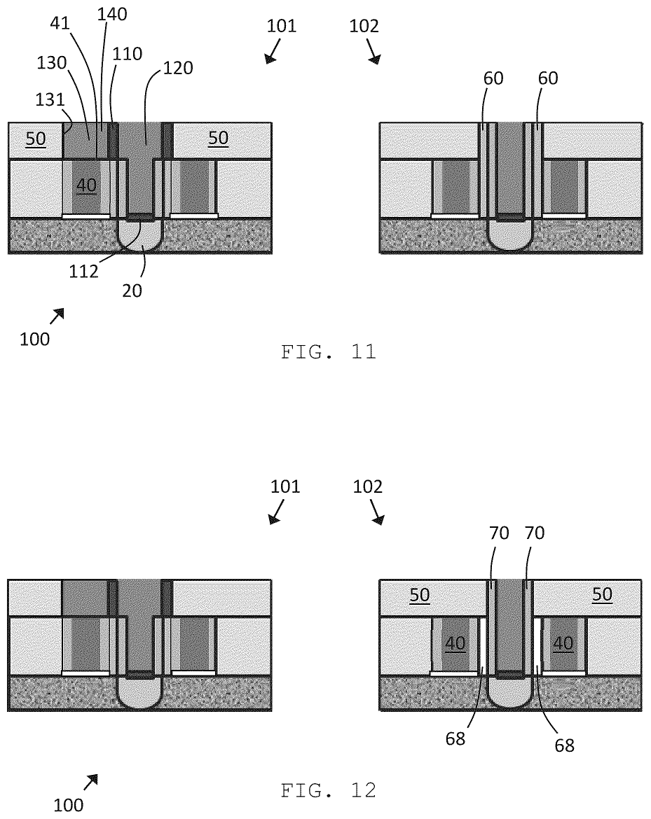

Referring now to FIG. 9, at operation S930, the method 900 (FIG. 1) includes performing a conversion process to convert upper portions 61 of semiconductor layer 60 and upper surface 21 of source/drain feature 20 to a metal-semiconductor intermetallic 110 in device region 101 and to convert upper surface 21 of source/drain feature 20 to a metal-semiconductor intermetallic 110 in device region 102. Specifically, metal-semiconductor intermetallic 111 is formed along the trench sidewalls 81 in device region 101 and metal-semiconductor intermetallic 112 is formed on the source/drain features 20 in device regions 101 and 102.

In certain embodiments, the conversion process is a thermal anneal process that causes the conversion layer to chemically react with the semiconductor material of the semiconductor layer 60 and source/drain feature 20.

The term “metal-semiconductor intermetallic”, similar to the terms metal metalloids, and metal-semiconductor compounds or alloys, refers to the material formed by the chemical reaction between the semiconductor layer 60 and source/drain feature 20.

In embodiments in which the semiconductor layer 60 and source/drain feature 20 are or include silicon, the metal-semiconductor intermetallic is silicide, such as titanium silicide, nickel silicide, cobalt silicide, or another suitable silicide. In other embodiments, the metal-semiconductor intermetallic may be germanide or another similar material suitable for forming a low-resistance electrical contact.

Operation S930 may be referred to as a self-aligned silicide (salicide) formation process.

Referring now to FIG. 10, at operation S932, the method 900 (FIG. 1) includes forming a conductive contact 120 in the trench 80 in device regions 101 and 102.

The conductive contacts 120 may include a barrier/adhesion layer (not shown) to prevent diffusion and provide better adhesion by the contacts 120. In an embodiment, the barrier layer is formed of one or more layers of titanium, titanium nitride, tantalum, tantalum nitride, or the like. The barrier layer is preferably formed through chemical vapor deposition, although other techniques could alternatively be used.

The contacts 120 may be formed of any suitable conductive material, such as a highly-conductive, low-resistive metal, elemental metal, transition metal, or the like. In an exemplary embodiment, the contacts 120 are formed of tungsten, although other materials, such as copper, could alternatively be utilized. In an embodiment in which the contacts 120 are formed of tungsten, the contacts 120 may be deposited by CVD techniques known in the art, although any method of formation could alternatively be used.

Operation S932 may include performing a chemical-mechanical planarization (CMP) process to remove any overburden portion of the contact material from over the upper surface of device 100 to define the contacts 120 within the trenches 80.

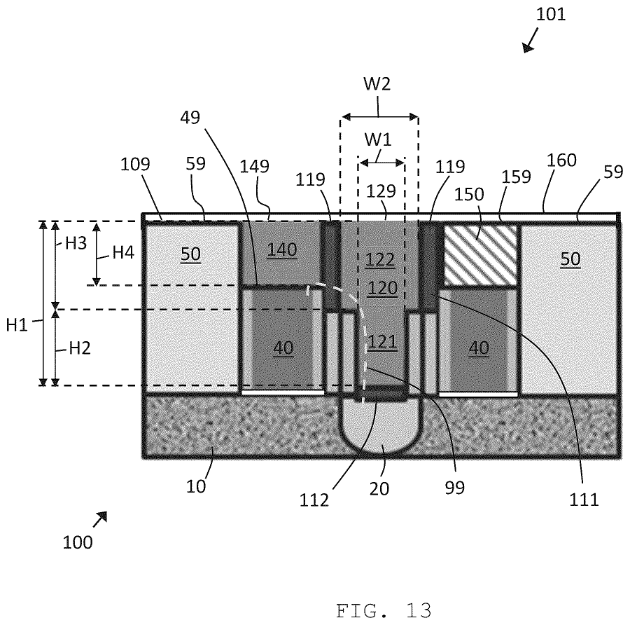

Referring now to FIG. 11, at operation S934, the method 900 (FIG. 1) includes etching a trench 130 into the upper dielectric layer 50 over selected metal gate structures 40. FIG. 11 illustrates that the trench 130 is only formed in device region 101, however, trenches 130 may be formed in device region 102 as well.

The trench 130 may be formed in accordance with known photolithography and etching techniques. The etching process may be an anisotropic or isotropic etch process. In an embodiment the etching process is an anisotropic dry etch process. In an embodiment, the etch process is continued until an upper surface 49 of the selected metal gate structure 40 is exposed, i.e., uncovered. As shown, the trench 80 is formed with sidewalls 131. Sidewalls 131 may be formed by upper dielectric layer 50 and metal-semiconductor intermetallic 110, in device region 101. Thus, no portion of the upper dielectric layer 50 remains between trench 130 and metal-semiconductor intermetallic 110. In device region 102, a trench 130 may be formed with sidewalls 131 defined by the upper dielectric layer 50 and semiconductor layer 60, or only by the upper dielectric layer 50.

Still referring to FIG. 11, method 900 (FIG. 1) may further include, at operation S936, forming a conductive contact 140 to the selected metal gate structure 40. For example, operation S936 forms the conductive contact 140 in trench 130 and in direct contact with metal-semiconductor intermetallic 110 in at least device region 101.

The conductive contact 140 may include a barrier/adhesion layer (not shown) to prevent diffusion and provide better adhesion by the contact 140. In an embodiment, the barrier layer is formed of one or more layers of titanium, titanium nitride, tantalum, tantalum nitride, or the like. The barrier layer is preferably formed through chemical vapor deposition, although other techniques could alternatively be used.

The contact 140 may be formed of any suitable conductive material, such as a highly-conductive, low-resistive metal, elemental metal, transition metal, or the like. In an exemplary embodiment, the contact 140 is formed of tungsten, although other materials, such as copper, could alternatively be utilized. In an embodiment in which the contacts 120 are formed of tungsten, the contacts 140 may be deposited by CVD techniques known in the art, although any method of formation could alternatively be used.

Operation S936 may include performing a chemical-mechanical planarization (CMP) process to remove any overburden portion of the contact material from over the upper surface of device 100 to define the contact 140 within the trench 130.

Referring now to FIG. 12, at operation S938, the method 900 (FIG. 1) includes removing the semiconductor layer 60 from device region 102. As shown, an air gap 68 is created by removing the semiconductor layer 60.

Still referring to FIG. 12, at operation S940, the method 900 (FIG. 1) includes expanding the dielectric layer 50 to seal the air gap 68 in device region 102 as shown. For example, an implant process may be performed to expand the dielectric layer 50.

FIG. 13 is a focused view of device region 101, to enable a clearer description of structures therein.

As shown in FIG. 13, at operation S942, the method 900 (FIG. 1) may include, optionally, forming an isolation cap 150 over the metal gate structure 40 that lacks a contact 140. For example, operation S942 may include etching the upper dielectric layer 50 to form a trench. Further, operation S942 may include depositing isolation material into the trench to form the isolation cap 150. The isolation cap 150 may be formed before or after the conductive contact 140.

In certain embodiments, the isolation cap 150 is formed from silicon oxide, zirconium oxide, aluminum oxide, or another suitable isolation material.

As shown, a CMP process may form the structure 100 with a planar upper surface 109 formed by the upper surface 59 of the upper dielectric layer 50, upper surface 149 of the conductive contact 140, upper surface 119 of the metal-semiconductor intermetallic 110, upper surface 129 of the conductive contact 120, and upper surface 159 of the isolation cap 150.

As shown in FIG. 13, at operation S944, the method 900 (FIG. 1) includes performing further processing, such as typical back-end-of-line processing. In certain embodiments, operation S944 includes forming an overlying layer 160 on the upper surface 109. For example, the overlying layer 160 may be a further layer or layers of dielectric material.

FIG. 13 illustrates that the source/drain contact 120 has a vertical height H1 equal to the vertical distance between the upper surface 109 and the metal-semiconductor intermetallic 112 of the source/drain feature 20. Specifically, the source/drain contact 120 extends downward from the upper surface 109 to the source/drain feature 20, and specifically, to the metal-semiconductor intermetallic 112 at the upper surface of the source/drain feature 20.

The source/drain contact 120 has a lower portion 121 with a reduced critical dimension or width W1 and an upper portion 122 with an increased critical dimension or width W2. As shown, width W2 is greater than width W1. The lower portion 121 has a vertical height H2 equal to the vertical distance between the upper surface 73 of dielectric layer 70 and the metal-semiconductor intermetallic 112 at the upper surface of the source/drain feature 20. The upper portion 122 has a vertical height H3 equal to the vertical distance between the upper surface 73 of dielectric layer 70 and the upper surface 109. Height H1 is equal to the sum of height H2 and height H3. As shown, sidewall metal-semiconductor intermetallic 111 also has the vertical height H3.

The gate contact 140 has a vertical height H4 equal to the vertical distance between the upper surface 49 of metal gate structure 40 and the upper surface 109.

In FIG. 13, height H3 is greater than height H4; however, height H3 may be equal to height H4 or may be less than height H4.

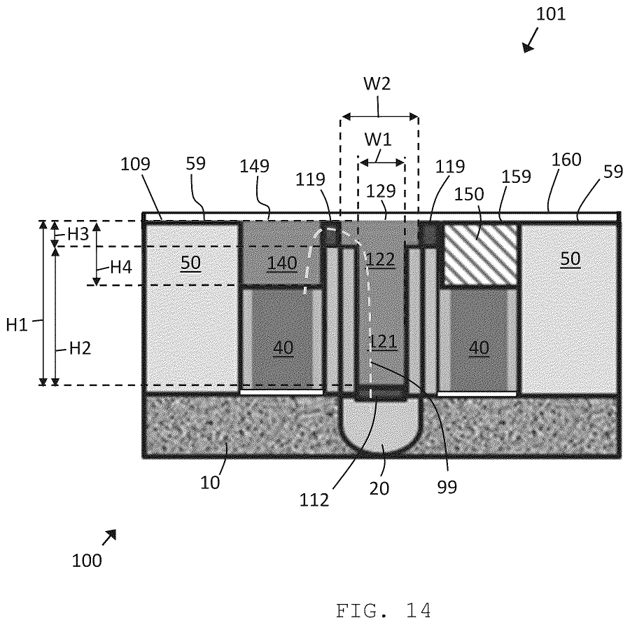

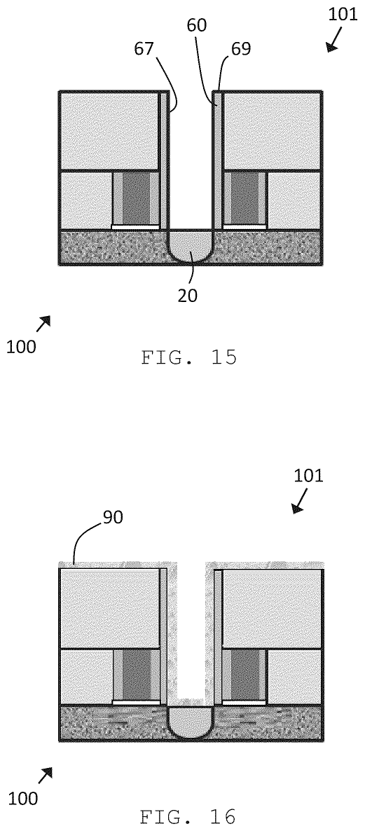

For example, FIG. 14 illustrates an embodiment in which height H3 is less than height H4. In certain embodiments, height H3 is at least 20% of height H4. In certain embodiments, a height H3 that is less than 20% of height H4 may increase contact resistance and impact circuit performance, such as SRAM data retention. In some embodiments, height H3 is at least 5%, at least 10%, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, at least 100%, at least 105%, at least 110%, or at least 115% of height H4.

In certain embodiments in which dielectric layer 70 is partially removed, height H3 is at most 130% of height H4. This upper limitation may optimize the conversion, or silicide, process. For example, at dimensions of greater than 130% of height H4, the conversion process may require stricter processing without providing reciprocal or additional benefits to contact resistance or circuit performance, i.e., the processing cost may outweigh the performance benefit In some embodiments, height H3 is at most 25%, at most 30%, at most 35%, at most 40%, at most 45%, at most 50%, at most 55%, at most 60%, at most 65%, at most 70%, at most 75%, at most 80%, at most 85%, at most 90%, at most 95%, at most 100%, at most 105%, at most 110%, at most 115%, at most 120%, at most 125%, or at most 130% of height H4.

FIGS. 2 to 13 or 14 illustrate successive stages for fabricating a semiconductor structure or device 100 according to some embodiments. In FIGS. 2-14, operation S926 recesses the dielectric liner 70 and leaves a lower portion 72 of the dielectric liner 70.

In other embodiments, all of the dielectric liner 70 so that the entirety of the semiconductor layer 60 is uncovered. This embodiment is illustrated in FIGS. 15-20.

Specifically, FIG. 15 illustrates the stage of manufacturing of operation S926, in which all of the dielectric liner 70 has been removed from the device region 101, such that the inner surface 67 of the semiconductor layer 60 is uncovered from source/drain feature 20 to upper surface 69. FIGS. 15-20 do not illustrate device region 102, as processing in device region 102 is identical to the embodiment of FIGS. 2-14.

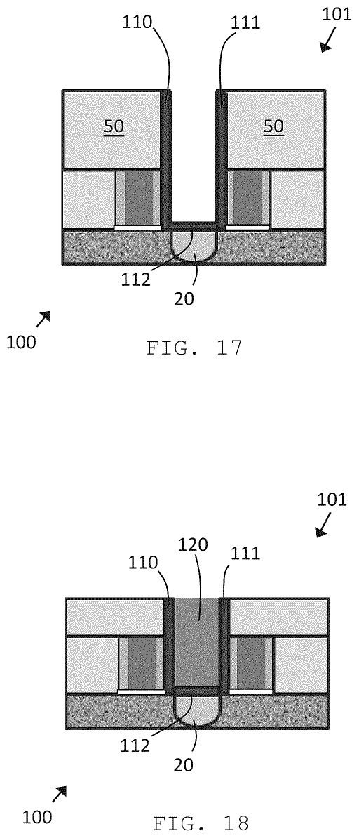

Referring now to FIG. 16, at operation S928, the method 900 (FIG. 1) includes depositing a conversion layer 90 over the structure 100. As shown, the conversion layer 90 is conformally deposited. As shown, the conversion layer 90 contacts the semiconductor layer 60 and the upper surface 21 of the source/drain feature 20, as well as the top surface of upper dielectric 50.

In certain embodiments, the conversion layer 90 is or includes a metal. For example, the conversion layer may be or may include titanium, nickel, cobalt, or another suitable metal.

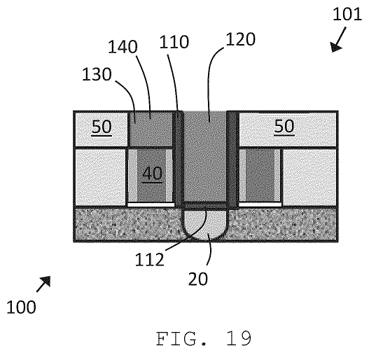

Referring now to FIG. 17, at operation S930, the method 900 (FIG. 1) includes performing a conversion process to convert all of semiconductor layer 60 and upper surface 21 of source/drain feature 20 to a metal-semiconductor intermetallic 110, i.e., sidewall metal-semiconductor intermetallic 111.

In certain embodiments, the conversion process is a thermal anneal process that causes the conversion layer to chemically react with the semiconductor material of the semiconductor layer 60 and source/drain feature 20.

Referring now to FIG. 18, at operation S932, the method 900 (FIG. 1) includes forming a conductive contact 120 in the trench 80.

Operation S932 may include performing a chemical-mechanical planarization (CMP) process to remove any overburden portion of the contact material from over the upper surface of device 100 to define the contact 120 within the trenches 80.

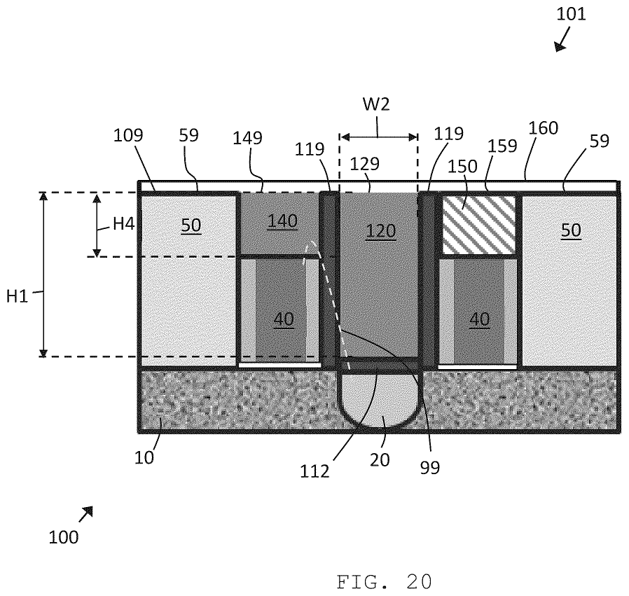

Referring now to FIG. 19, at operation S934, the method 900 (FIG. 1) includes etching a trench 130 into the upper dielectric layer 50 over selected metal gate structures 40.

Still referring to FIG. 19, method 900 (FIG. 1) may further include, at operation S936, forming a conductive contact 140 to the selected metal gate structure 40. For example, operation S936 forms the conductive contact 140 in trench 130 and in direct contact with metal-semiconductor intermetallic 110.

Operation S936 may include performing a chemical-mechanical planarization (CMP) process to remove any overburden portion of the contact material from over the upper surface of device 100 to define the contact 140 within the trench 130.

Referring now to FIG. 20, at operation S942, the method 900 (FIG. 1) may include, optionally, forming an isolation cap 150 over the metal gate structure 40 that lacks a contact 140. For example, operation S942 may include etching the upper dielectric layer 50 to form a trench. Further, operation S942 may include depositing isolation material into the trench to form the isolation cap 150. The isolation cap 150 may be formed before or after the conductive contact 140. In certain embodiments, the isolation cap 150 is formed from silicon oxide, zirconium oxide, aluminum oxide, or another suitable isolation material.

As shown, a CMP process may form the structure 100 with a planar upper surface 109 formed by the upper surface 59 of the upper dielectric layer 50, upper surface 149 of the conductive contact 140, upper surface 119 of the metal-semiconductor intermetallic 110, upper surface 129 of the conductive contact 120, and upper surface 159 of the isolation cap 150.

As shown in FIG. 20, at operation S944, the method 900 (FIG. 1) includes performing further processing, such as typical back-end-of-line processing. In certain embodiments, operation S944 includes forming an overlying layer 160 on the upper surface 109. For example, the overlying layer 160 may be a further layer or layers of dielectric material.

FIG. 20 illustrates that the source/drain contact 120 has a same width W2 for the entirety of vertical height H1 equal to the vertical distance between the upper surface 109 and the metal-semiconductor intermetallic 112 of the source/drain feature 20.

In the embodiments of FIGS. 13, 14 and 20, height H4 may be at least 5% of height H1, such as at least 10%, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, or at least 95% of height H1. Further, height H4 may be at most 5%, at most 10%, at most 15%, at most 20%, at most 25%, at most 30%, at most 35%, at most 40%, at most 45%, at most 50%, at most 55%, at most 60%, at most 65%, at most 70%, at most 75%, at most 80%, at most 85%, at most 90%, or at most 95% of height H1.

As shown in FIGS. 13, 14, and 20, an electrical path 99 is formed directly from the source/drain feature 20, through source/drain metal-semiconductor intermetallic 112, source/drain contact 120, sidewall semiconductor intermetallic 111, gate contact 140, to metal gate structure 40. As shown, the electrical path 99 does not extend through the upper surface 129 of source/drain contact 120 and does not extend through the upper surface 149 of gate contact 140. For example, the entire electrical path 99 is located between the overlying layer 160 and the substrate 10. Further, the electrical path 99 travels in a lateral direction when exiting/entering the source/drain contact 120, sidewall semiconductor intermetallic 111, and gate contact 140.

As compared to a traditional butted contact used to connect a source/drain contact 120 and a gate contact 140, the embodiments herein provide an electrical path 99 between the source/drain contact 120 and the gate contact 140 that is shorter. Further, the width of the flow path out of the source/drain contact 120 is increased, as the height H3 of the sidewall metal-semiconductor intermetallic 111 may be greater than the width W1 of the top end of a traditional source/drain contact 120. More specifically, the limiting cross-sectional area of the electrical path 99 is not the width W1, which may be reduced by scaling. Also, as shown in embodiments herein, the source/drain contact 120 has an increased width W2 in the upper portion, where width W2 is equal to the sum of width W1 plus the thickness of two dielectric layers 70. Contact resistance may be reduced by eliminating additional contact length over the upper surfaces 129 and 149.

In one embodiment, a method includes forming a trench over a semiconductor substrate, wherein the trench has a trench sidewall; forming a semiconductor liner on the trench sidewall; converting at least a portion of the semiconductor liner to a metal-semiconductor intermetallic; forming a first conductive contact in the trench, wherein the first conductive contact contacts the metal-semiconductor intermetallic; and forming a second conductive contact adjacent to the metal-semiconductor intermetallic.

In certain embodiments, a conductive path is formed from the first conductive contact to the second conductive contact through the metal-semiconductor intermetallic.

In certain embodiments of the method, the semiconductor liner is silicon and the metal-semiconductor intermetallic is silicide.

In certain embodiments, the method further includes forming a source/drain feature in and/or over the substrate, wherein the trench is located over the source/drain feature, and wherein the first conductive contact is a source/drain contact.

In certain embodiments, the method further includes forming a gate structure over the substrate, wherein the second conductive contact is a gate contact.

In certain embodiments, the method further includes forming a first gate structure and a second gate structure over the substrate, wherein the trench is formed between the first gate structure and the second gate structure; and wherein the second conductive contact is a gate contact located on the first gate structure; and forming an isolation cap over the second gate structure, wherein the first conductive contact is located between the second conductive contact and the isolation cap.

In certain embodiments, the method further includes forming a dielectric liner on the semiconductor liner; and recessing at least a portion of the dielectric liner to define an uncovered portion of the semiconductor liner, wherein converting at least a portion of the semiconductor liner to the metal-semiconductor intermetallic includes converting the uncovered portion of the semiconductor liner to the metal-semiconductor intermetallic.

In certain embodiments of the method, recessing at least a portion of the dielectric liner includes removing all of the dielectric liner.

In certain embodiments, the method further includes forming a sacrificial structure over the substrate; forming a source/drain feature in and/or over the substrate adjacent to sacrificial structure; forming a dielectric segment adjacent to the sacrificial structure and over the source/drain feature; removing the sacrificial structure to form a gate cavity; forming a gate structure in the gate cavity; and forming an upper dielectric layer over the gate structure and the dielectric segment, wherein forming the trench over the semiconductor substrate includes etching the upper dielectric layer and the dielectric segment to form the trench and uncover the source/drain feature; wherein the first conductive contact contacts the source/drain feature, wherein the second conductive contact contacts the gate structure, and wherein the conductive path is formed from the source/drain feature to the gate structure.

In another embodiment, a method includes defining a first device region and a second device region of a semiconductor substrate; performing a feature formation process to form a first feature on and/or over the substrate in the first device region and a second feature on and/or over the substrate in the second device region; performing an etch process to form a first trench over the first feature and to form a second trench over the second feature, wherein each trench has a trench sidewall; performing a deposition process to form a first semiconductor liner on the trench sidewall of the first trench and a second semiconductor liner on the trench sidewall of the second trench; and performing a conversion process to convert upper portions of the first feature and the second feature to a metal-semiconductor intermetallic and to selectively convert at least a portion of the first semiconductor liner to a metal-semiconductor intermetallic, wherein the second semiconductor liner is not converted to the metal-semiconductor intermetallic.

In certain embodiments, the method further includes performing a first contact formation process to form a first source/drain contact in the first trench and a second source/drain contact in the second trench.

In certain embodiments, the method further includes forming a first gate structure over the substrate in the first device region and a second gate structure over the substrate in the second device region; and performing a second contact formation process to form a gate source/drain contact in the first device region contacting the first gate structure and the metal-semiconductor intermetallic.

In certain embodiments of the method, performing the conversion process includes depositing a layer of conversion material over the first device region and the second device region, wherein the layer of conversion material contacts the upper portions of the first feature and the second feature and the portion of the first semiconductor liner; and performing an anneal process to convert the upper portions of the first feature and the second feature and the portion of the first semiconductor liner to the metal-semiconductor intermetallic.

In certain embodiments of the method, the upper portions of the first feature and the second feature and the portion of the first semiconductor liner include silicon; the layer of conversion material is selected from titanium, nickel, and cobalt; and the metal-semiconductor intermetallic is selected from titanium silicide, nickel silicide, and cobalt silicide.

In certain embodiments, the method further includes performing a second deposition process to form a first dielectric liner on the first semiconductor liner and a second dielectric liner on the second semiconductor liner; and performing a recess process to remove at least an upper portion of the first dielectric liner to uncover the portion of the first semiconductor liner.

In certain embodiments of the method, performing the recess process includes removing all of the first dielectric liner to uncover all of the first semiconductor liner.

In another embodiment, a semiconductor structure has an upper surface and includes a first conductive contact extending downward from the upper surface of the structure; a second conductive contact extending downward from the upper surface of the structure; and a metal-semiconductor intermetallic located between and contacting the first conductive contact and the second conductive contact.

In certain embodiments, the structure further includes a source/drain feature located under and in contact with the first conductive contact; and a gate structure located under and in contact with the second conductive contact.

In certain embodiments of the structure, the metal-semiconductor intermetallic extends downward from the upper surface and terminates at a bottom surface located a first distance from the upper surface; the second conductive contact extends downward from the upper surface and terminates at a bottom surface located a second distance from the upper surface; and the first distance is from 20% of the second distance to 105% of the second distance.

In certain embodiments of the structure, the metal-semiconductor intermetallic extends downward from the upper surface and terminates at a bottom surface located a first distance from the upper surface; the first conductive contact has an upper portion with a first width that extends downward from the upper surface to a first depth; the first conductive contact has a lower portion with a second width that extends downward from the first depth to the source/drain feature for a second depth; and the first width is greater than the second width.

In certain embodiments of the structure, the gate structure is a first gate structure and the semiconductor structure further includes a second gate structure, wherein the first conductive contact is located between the first gate structure and the second gate structure; and an isolation cap located over the second gate structure, wherein the first conductive contact is located between the second conductive contact and the isolation cap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a trench over a semiconductor substrate, wherein the trench has a trench sidewall;
forming a semiconductor liner on the trench sidewall;
converting at least a portion of the semiconductor liner to a metal-semiconductor intermetallic;
forming a first conductive contact in the trench, wherein the first conductive contact contacts the metal-semiconductor intermetallic; and
forming a second conductive contact adjacent to the metal-semiconductor intermetallic.

2. The method of claim 1, wherein a conductive path is formed from the first conductive contact to the second conductive contact through the metal-semiconductor intermetallic.

3. The method of claim 1, further comprising forming a source/drain feature in and/or over the substrate, wherein the trench is located over the source/drain feature, and wherein the first conductive contact is a source/drain contact.

4. The method of claim 1, further comprising forming a gate structure over the substrate, wherein the second conductive contact is a gate contact.

5. The method of claim 1 further comprising:
forming a first gate structure and a second gate structure over the substrate, wherein the trench is formed between the first gate structure and the second gate structure; and wherein the second conductive contact is a gate contact located on the first gate structure; and
forming an isolation cap over the second gate structure, wherein the first conductive contact is located between the second conductive contact and the isolation cap.

6. The method of claim 1 further comprising:
forming a dielectric liner on the semiconductor liner; and
recessing at least a portion of the dielectric liner to define an uncovered portion of the semiconductor liner, wherein converting at least a portion of the semiconductor liner to the metal-semiconductor intermetallic comprises converting the uncovered portion of the semiconductor liner to the metal-semiconductor intermetallic.

7. The method of claim 6, wherein recessing at least a portion of the dielectric liner comprises removing all of the dielectric liner.

8. The method of claim 1, further comprising:
forming a sacrificial structure over the substrate;
forming a source/drain feature in and/or over the substrate adjacent to sacrificial structure;
forming a dielectric segment adjacent to the sacrificial structure and over the source/drain feature;
removing the sacrificial structure to form a gate cavity;
forming a gate structure in the gate cavity; and
forming an upper dielectric layer over the gate structure and the dielectric segment, wherein forming the trench over the semiconductor substrate comprises etching the upper dielectric layer and the dielectric segment to form the trench and uncover the source/drain feature;
wherein the first conductive contact contacts the source/drain feature, wherein the second conductive contact contacts the gate structure, and wherein the conductive path is formed from the source/drain feature to the gate structure.

9. A method comprising:
defining a first device region and a second device region of a semiconductor substrate;
performing a feature formation process to form a first feature on and/or over the substrate in the first device region and a second feature on and/or over the substrate in the second device region;
performing an etch process to form a first sidewall over the first feature and to form a second sidewall over the second feature;
performing a deposition process to form a first semiconductor liner on the first sidewall and a second semiconductor liner on the second sidewall; and
performing a conversion process to convert upper portions of the first feature and the second feature to a metal-semiconductor intermetallic and to selectively convert at least a portion of the first semiconductor liner to a metal-semiconductor intermetallic, wherein the second semiconductor liner is not converted to the metal-semiconductor intermetallic.

10. The method of claim 9, further comprising performing a first contact formation process to form a first source/drain contact in the first device region and a second source/drain contact in the second device region.

11. The method of claim 10, further comprising:
forming a first gate structure over the substrate in the first device region and a second gate structure over the substrate in the second device region; and
performing a second contact formation process to form a gate source/drain contact in the first device region contacting the first gate structure and the metal-semiconductor intermetallic.

12. The method of claim 9, wherein performing the conversion process comprises:
depositing a layer of conversion material over the first device region and the second device region, wherein the layer of conversion material contacts the upper portions of the first feature and the second feature and the portion of the first semiconductor liner; and
performing an anneal process to convert the upper portions of the first feature and the second feature and the portion of the first semiconductor liner to the metal-semiconductor intermetallic.

13. The method of claim 12, wherein:
the upper portions of the first feature and the second feature and the portion of the first semiconductor liner comprise silicon;
the layer of conversion material is selected from titanium, nickel, and cobalt; and
the metal-semiconductor intermetallic is selected from titanium silicide, nickel silicide, and cobalt silicide.

14. The method of claim 9, further comprising:
performing a second deposition process to form a first dielectric liner on the first semiconductor liner and a second dielectric liner on the second semiconductor liner; and
performing a recess process to remove at least an upper portion of the first dielectric liner to uncover the portion of the first semiconductor liner.

15. The method of claim 14, wherein performing the recess process comprises removing all of the first dielectric liner to uncover all of the first semiconductor liner.

16. A semiconductor structure having an upper surface and comprising:
a first conductive contact extending downward from the upper surface of the structure;
a second conductive contact extending downward from the upper surface of the structure; and
a metal-semiconductor intermetallic located between and contacting the first conductive contact and the second conductive contact.

17. The semiconductor structure of claim 16, further comprising:
a source/drain feature located under and in contact with the first conductive contact; and
a gate structure located under and in contact with the second conductive contact.

18. The semiconductor structure of claim 17, wherein:
the metal-semiconductor intermetallic extends downward from the upper surface and terminates at a bottom surface located a first distance from the upper surface;
the second conductive contact extends downward from the upper surface and terminates at a bottom surface located a second distance from the upper surface; and
the first distance is from 20% of the second distance to 105% of the second distance.

19. The semiconductor structure of claim 17, wherein:
the metal-semiconductor intermetallic extends downward from the upper surface and terminates at a bottom surface located a first distance from the upper surface;
the first conductive contact has an upper portion with a first width that extends downward from the upper surface to a first depth;
the first conductive contact has a lower portion with a second width that extends downward from the first depth to the source/drain feature for a second depth; and
the first width is greater than the second width.

20. The semiconductor structure of claim 17, wherein the gate structure is a first gate structure and wherein the semiconductor structure further comprises:
a second gate structure, wherein the first conductive contact is located between the first gate structure and the second gate structure; and
an isolation cap located over the second gate structure, wherein the first conductive contact is located between the second conductive contact and the isolation cap.
